(19) United States
(12) Patent Application Publication
(10) Pub. No.: US 2024/0313725 A1
(43) Pub. Date: Sep. 19, 2024

(54) HIGH VOLTAGE NOISE CANCELLATION

(71) Applicant: Applied Materials Israel Ltd., Rehovot (IL)

(72) Inventors: Shem Yehoyda Prazot Ofenburg, Jerusalem (IL); Noam Dori, Rehovot (IL)

(73) Assignee: Applied Materials Israel Ltd., Rehovot (IL)

(21) Appl. No.: 18/122,646

(22) Filed: Mar. 16, 2023

(51) Int. Cl. H03F 3/45; H03F 1/26

(52) U.S. Cl. CPC H03F 3/45497; H03F 1/26; H03F 3/45475

(57) ABSTRACT

A high voltage noise reduction unit that includes (i) an input that is configured to receive a high voltage input signal (HVIS); (ii) a positive isolated supply unit that is configured to receive the HVIS and to output a positive supply signal that floats on the HVIS; (iii) a negative isolated supply unit that is configured to receive the HVIS and to output a negative supply signal that floats on the HVIS; (iv) a low pass filter that is configured to filter the HVIS to provide a filtered high voltage signal; and (v) an amplifier that is configured to receive the positive supply signal, to receive the negative supply signal, to receive the filtered high voltage signal and amplify the filtered high voltage signal to provide a high voltage output signal.

### BACKGROUND OF THE INVENTION

Charged particle systems such as electron microscopes may illuminate a sample with an electron beam. The generating of the electron beam may require a provision of high voltage signals to the electron microscope. The term high voltage refers to a voltages that may exceed one thousand volts, five thousand volts, ten thousand volts, fifteen thousand volts, twenty thousand volts, and even more.

The high voltage signals are supplied by a high voltage source which is very noisy—as the noise level is a function of various factors-including the nominal voltage of the voltage source. For example—assuming that the nominal voltage is ten million times larger than the noise level. Under this assumption a low voltage supply having a nominal voltage of ten volts will also generate noise of about one microvolt. On the other hand a high voltage supply having a nominal voltage of ten thousand volts will generate a noise of about ten millivolts.

Noisy high voltage signals may reduce the accuracy of electron microscopy measurement in various manners, for example, by distorting a scan pattern followed by the electron beam, by impacting detection signals generated by sensors of the electron microscope, and the like.

High voltage noises may be suppressed by using a passive filter that should endue the high voltage signals for a long duration and are very big and expensive. Using high power active components requires to use noisy high voltage supply.

There is a growing need to provide an efficient noise reduction solution for reducing noises of high power signals.

### BRIEF SUMMARY OF THE INVENTION

There may be provided a high voltage noise reduction unit. The high voltage noise reduction unit may include (i) an input that is configured to receive a high voltage input signal having a value of at least five hundred volts; (ii) a positive isolated supply unit that is configured to receive the high voltage input signal and to output a positive supply signal that floats on the high voltage input signal; (iii) a negative isolated supply unit that is configured to receive the high voltage input signal and to output a negative supply signal that floats on the high voltage input signal; (iv) a low pass filter that is configured to filter the high voltage input signal to provide a filtered high voltage signal; and (v) an amplifier that is configured to receive the positive supply signal, to receive the negative supply signal, to receive the filtered high voltage signal and amplify the filtered high voltage signal to provide a high voltage output signal

There may be provided a method for high voltage noise reduction unit, the method may include (a) receiving a high voltage input signal, by (i) an input of the high voltage noise reduction unit, (ii) a positive isolated supply unit, (iii) a negative isolated supply unit, and (iv) a low pass filter; wherein the high voltage input signal has a value of at least five hundred volts; (b) outputting, by the positive isolated supply unit, a positive supply signal that floats on the high voltage input signal; (c) outputting, by the negative isolated supply unit, a negative supply signal that floats on the high voltage input signal; (d) filtering, by the low pass filter, the high voltage input signal to provide a filtered high voltage signal; (e) receiving, by an amplifier, the positive supply signal, the negative supply signal and the filtered high voltage signal; and (f) amplifying the filtered high voltage signal, by the amplifier, to provide a high voltage output signal.

There may be provided a high voltage noise reduction unit. The high voltage noise reduction unit may include (i) an input that is configured to receive a high voltage input signal having a value of at least five hundred volts; (ii) a positive isolated supply unit that is configured to receive the high voltage input signal and to output a positive supply signal that floats on the high voltage input signal; (iii) a negative isolated supply unit that is configured to receive the high voltage input signal and to output a negative supply signal that floats on the high voltage input signal; (iv) a low pass filter that is configured to filter the high voltage input signal to provide a filtered high voltage signal; and (v) a buffer that is configured to receive the positive supply signal, to receive the negative supply signal, to receive the filtered high voltage signal and to output a high voltage output signal that equals the filtered high voltage signal.

### BRIEF DESCRIPTION OF THE DRAWINGS

The subject matter regarded as the invention is particularly pointed out and distinctly claimed in the concluding portion of the specification. The invention, however, both as to organization and method of operation, together with specimen s, features, and advantages thereof, may best be understood by reference to the following detailed description when read with the accompanying drawings in which:

FIG. 1 illustrates an example of a noise reduction unit;

FIG. 2 illustrates an example of a noise reduction unit;

FIG. 3 illustrates an example of a noise reduction unit;

FIG. 4 illustrates an example of a method; and

FIG. 5 illustrates an example of a method.

It will be appreciated that for simplicity and clarity of illustration, elements shown in the figures have not necessarily been drawn to scale. For example, the dimensions of some of the elements may be exaggerated relative to other elements for clarity. Further, where considered appropriate, reference numerals may be repeated among the figures to indicate corresponding or analogous elements.

### DETAILED DESCRIPTION OF THE INVENTION

In the following detailed description, numerous specific details are set forth in order to provide a thorough understanding of the embodiments of the disclosure.

However, it will be understood by those skilled in the art that the present embodiments of the disclosure may be practiced without these specific details. In other instances, well-known methods, procedures, and components have not been described in detail so as not to obscure the present embodiments of the disclosure.

The subject matter regarded as the embodiments of the disclosure is particularly pointed out and distinctly claimed in the concluding portion of the specification. The embodiments of the disclosure, however, both as to organization and method of operation, together with objects, features, and advantages thereof, may best be understood by reference to the following detailed description when read with the accompanying drawings.

It will be appreciated that for simplicity and clarity of illustration, elements shown in the figures have not necessarily been drawn to scale. For example, the dimensions of some of the elements may be exaggerated relative to other elements for clarity. Further, where considered appropriate, reference numerals may be repeated among the figures to indicate corresponding or analogous elements.

Because the illustrated embodiments of the disclosure may for the most part, be implemented using electronic components and circuits known to those skilled in the art, details will not be explained in any greater extent than that considered necessary as illustrated above, for the understanding and appreciation of the underlying concepts of the present embodiments of the disclosure and in order not to obfuscate or distract from the teachings of the present embodiments of the disclosure.

Any reference in the specification to a method should be applied mutatis mutandis to a high voltage noise reduction unit capable of executing the method.

Any reference in the specification to a high voltage noise reduction unit should be applied mutatis mutandis to a method that may be executed by the high voltage noise reduction unit.

The term and/or means additionally or alternatively. For example A and/or B means only A, or only B or A and B.

There may be provided a high voltage noise reduction unit that mostly uses low voltage components that are significantly less noisy, much smaller and are significantly less expensive than corresponding high voltage components. The low voltage components may be off the shelf components and not tailor made components.

The voltage across each of the low voltage components is maintained low, in order not to expose the low power components to high voltage differences, so that the voltage difference between different ports or terminals of each low voltage component remains low. The high voltage noise reduction unit virtually breaks the linkage between the nominal voltage of the output voltage and noise.

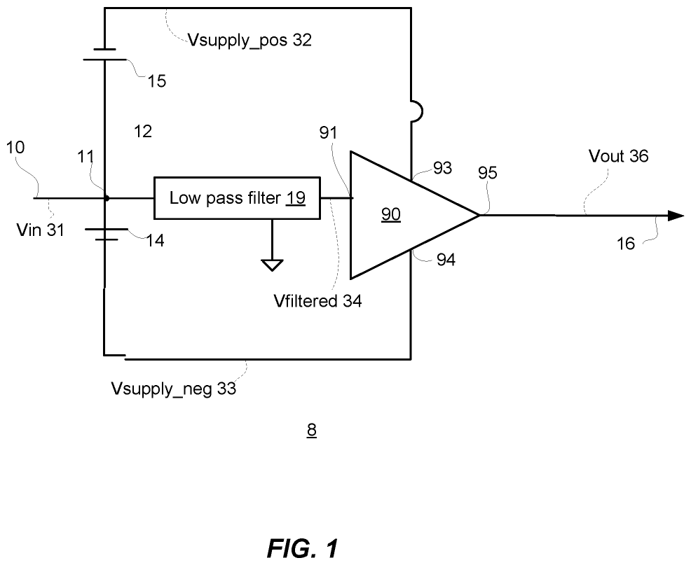

FIG. 1 illustrate an example of a high voltage noise reduction unit 8 that includes:
a. Input 10 that is configured to receive a high voltage input signal (Vin 31) having a value of at least five hundred volts.
b. Positive isolated supply unit 15 that is configured to receive (via node 11) the high voltage input signal (Vin 31) and to output a positive supply signal (Vsupply_pos 32) that floats on the high voltage input signal.
c. Negative isolated supply unit 14 that is configured to receive (via node 11) the high voltage input signal (Vin 31) and to output a negative supply signal Vsupply_neg 33) that floats on the high voltage input signal.
d. Low pass filter 19 that is configured to filter the high voltage input signal to provide a filtered high voltage signal (Vfiltered 34).
e. Buffer 90 that is configured to receive the positive supply signal (by buffer positive supply port 93), to receive the negative supply signal (by buffer negative supply port 94), to receive the filtered high voltage signal (by buffer input 91) and output (from buffer output port 95) a high voltage output signal (Vout 36) that equals the filtered high voltage signal.

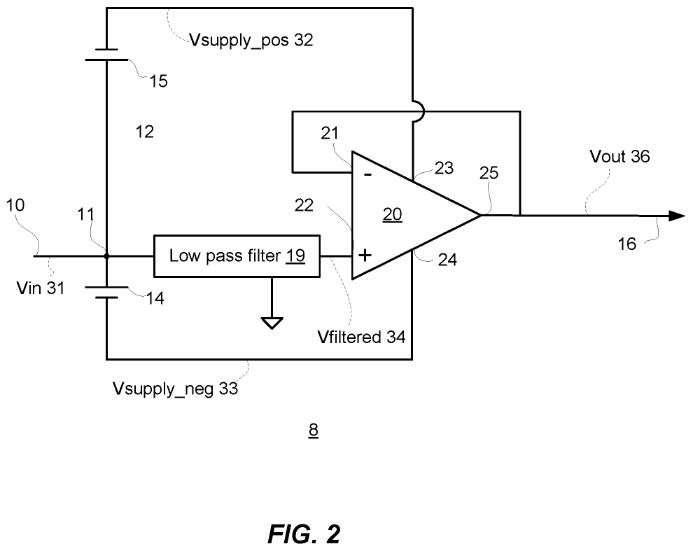

FIG. 2 illustrate an example of a high voltage noise reduction unit 8 that includes:
a. Input 10 that is configured to receive a high voltage input signal (Vin 31) having a value of at least five hundred volts.
b. Positive isolated supply unit 15 that is configured to receive (via node 11) the high voltage input signal (Vin 31) and to output a positive supply signal (Vsupply_pos 32) that floats on the high voltage input signal.
c. Negative isolated supply unit 14 that is configured to receive (via node 11) the high voltage input signal (Vin 31) and to output a negative supply signal Vsupply_neg 33) that floats on the high voltage input signal.
d. Low pass filter 19 that is configured to filter the high voltage input signal to provide a filtered high voltage signal (Vfiltered 34).
e. Amplifier 20 that is configured to receive the positive supply signal, to receive the negative supply signal, to receive the filtered high voltage signal and amplify the filtered high voltage signal to provide high voltage output signal (Vout 36).

The amplification may be a power amplification, whereas there may be no significant difference between the voltage level of the filtered high voltage signal (Vfiltered 34) and the high voltage output signal (Vout 36).

The amplification factor of the amplifier may be one, may exceed one, and the like.

Each one of the amplifier, the positive isolated supply unit, and the negative isolated supply unit are low voltage components that are subjected to low voltage differences that do not exceed 24 volts.
a. The positive isolated supply unit 15 is exposed to a low value voltage difference between high voltage input signal (Vin 31) and the positive supply signal (Vsupply_pos 32) that floats on the high voltage input signal.
b. The negative isolated supply unit 14 is exposed to a low value voltage difference between high voltage input signal (Vin 31) and the negative supply signal (Vsupply_neg 33) that floats on the high voltage input signal.
c. The amplifier 20 is exposed to low value voltage differences between the filtered high voltage signal (Vfiltered 34), the negative supply signal (Vsupply_neg 33), the positive supply signal (Vsupply_pos 32) and the output signal (Vout 36) when keeping the output signal close to the filtered high voltage signal.

Amplifier 20 includes:
a. Inverting input 21.
b. Noninverting input 22 that is configured to receive filtered high voltage signal (Vfiltered 34).
c. Negative supply port 24 that is configured to receive the negative supply signal (Vsupply_neg 33).
d. Positive supply port 23 that is configured to receive the positive supply signal (Vsupply_pos 34).
e. Output port 25 that is in communication with the inverting input 21 and is configured to output the high voltage output signal (Vout 36) via output 16 of the high voltage noise reduction unit 8.

The low pass filter 19 is electrically coupled between node 11 and the noninverting input 22.

The amplifier may act as a buffer or may be replaced by a buffer (see FIG. 1) for buffering between the filtered high voltage signal (Vfiltered 34), and the high voltage output signal (Vout 36).

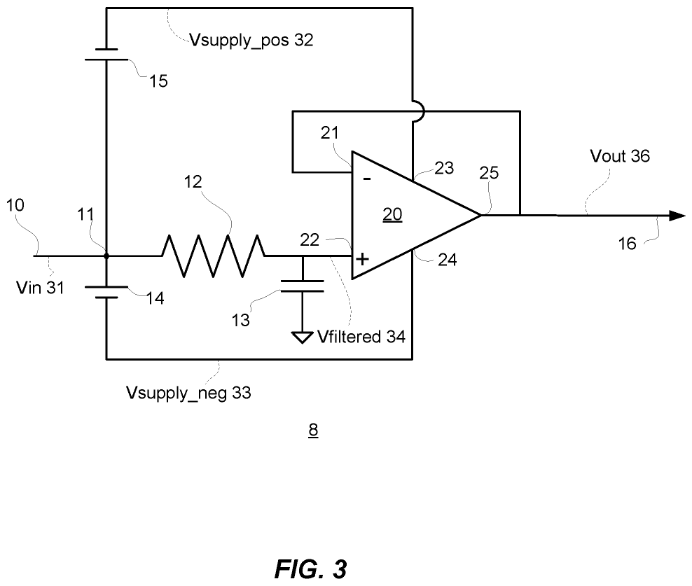

FIG. 3 illustrate high voltage noise reduction unit 8 where the low pass filter 19 includes a resistor 12 and a capacitor 13. The resistor 12 is a high impedance resistor and has a resistance that is not lower than one megaohms.

The resistor is electrically coupled between node 11 and the noninverting input 22, while the capacitor 13 is electrically coupled between the noninverting input 22 and the ground.

The capacitance (C) of capacitor may be a function of the cut off frequency (Fc) of the low pass filter, and the resistance (R) of resistor 13. Especially C=1/(2π*R*Fc). Because R is very high (at least 1, 10, 50, 100 Megaohms), and Fc is relatively low (for example 1, 10, 100 Hz, and the like)—the value of C may be very small—for example in the range of 10⁻¹² till 10⁻⁹ Farads—which result in a capacitor of a very small size.

The resistor 13 may significantly limit the current that flow through the resistor and impose limitation on the power of the input high voltage signal. On the other hand, the impedance that the output 16 will see is significantly lower than the resistance of the resistor and a much high power can be outputted by the high voltage noise reduction unit.

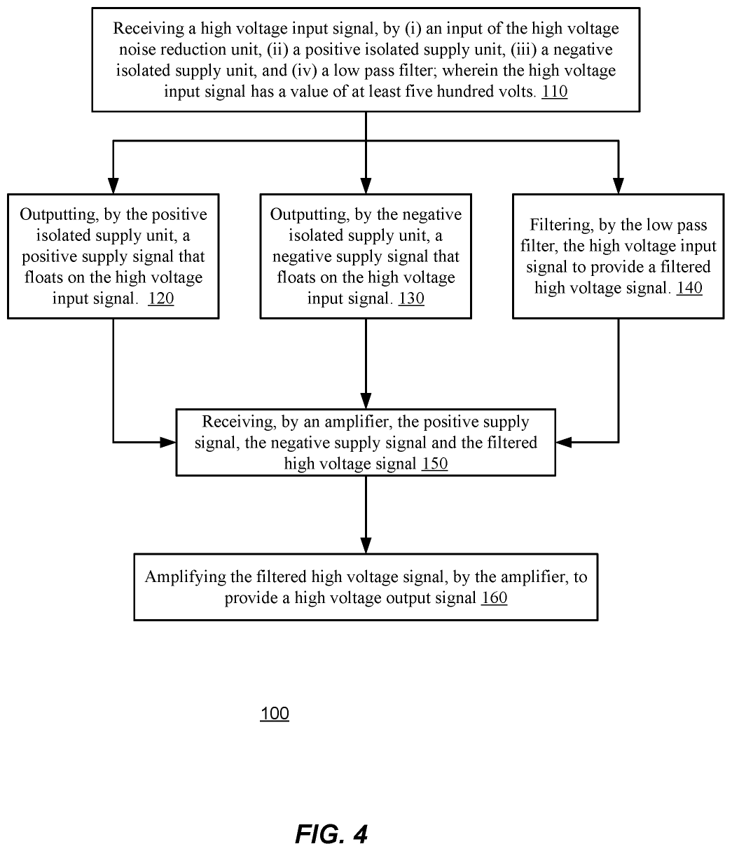

FIG. 4 illustrates a method 100 for high voltage noise reduction unit.

Method 100 may start by step 110 of receiving a high voltage input signal, by (i) an input of the high voltage noise reduction unit, (ii) a positive isolated supply unit, (iii) a negative isolated supply unit, and (iv) a low pass filter; wherein the high voltage input signal has a value of at least five hundred volts.

Step 110 may be followed by steps 120, 130 and 140.

Step 120 may include outputting, by the positive isolated supply unit, a positive supply signal that floats on the high voltage input signal.

Step 130 may include outputting, by the negative isolated supply unit, a negative supply signal that floats on the high voltage input signal.

Step 140 may include filtering, by the low pass filter, the high voltage input signal to provide a filtered high voltage signal.

Steps 120, 130 and 140 may be followed by step 150 of receiving, by an amplifier, the positive supply signal, the negative supply signal and the filtered high voltage signal.

Step 150 may be followed by step 160 of amplifying the filtered high voltage signal, by the amplifier, to provide a high voltage output signal. Step 160 may include outputting, by the output port, the high voltage output signal.

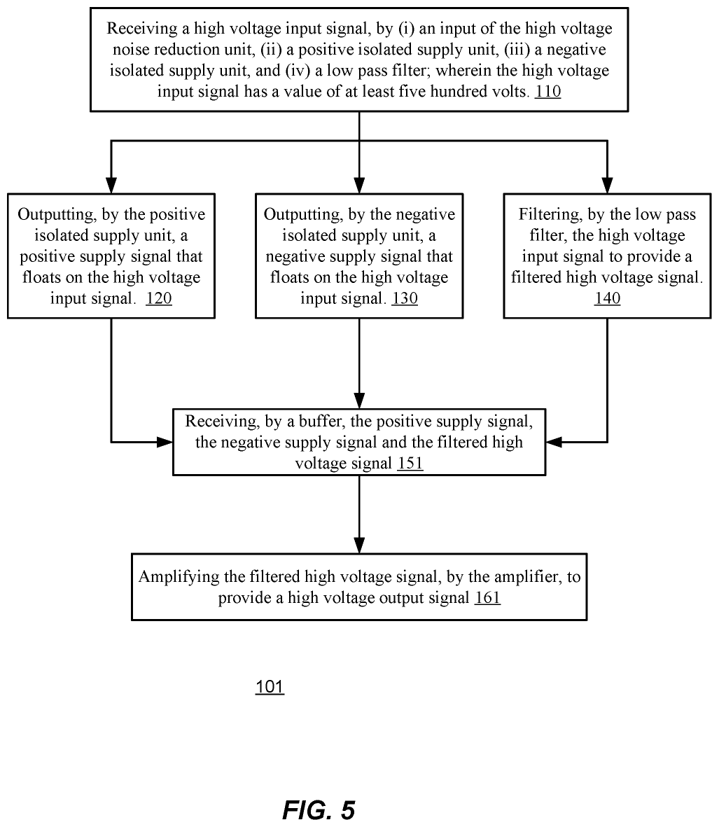

FIG. 5 illustrates a method 101 for high voltage noise reduction unit.

Method 101 may start by step 110.

Step 110 may be followed by steps 120, 130 and 140.

Steps 120, 130 and 140 may be followed by step 151 of receiving, by a buffer, the positive supply signal, the negative supply signal and the filtered high voltage signal.

Step 151 may be followed by step 161 of outputting, by the buffer, the high voltage output signal, whereas the high voltage output signal may equal the filtered high voltage signal.

The method may be executed by any of the high voltage noise reduction unit of FIG. 1, 2 or 3.

The amplifier may include an inverting input, a noninverting input, a negative supply port, a positive supply port and an output port that is in communication with the inverting input. Step 150 may include receiving the negative supply signal by the negative supply port and receiving the positive supply signal by the positive supply port.

In the foregoing specification, the embodiments of the disclosure have been described with reference to specific examples of embodiments. It will, however, be evident that various modifications and changes may be made therein without departing from the broader spirit and scope of the appended claims.

Moreover, the terms “front,” “back,” “top,” “bottom,” “over,” “under” and the like in the description and in the claims, if any, are used for descriptive purposes and not necessarily for describing permanent relative positions. It is understood that the terms so used are interchangeable under appropriate circumstances such that the embodiments of the disclosure described herein are, for example, capable of operation in other orientations than those illustrated or otherwise described herein.

Each signal described herein may be designed as positive or negative logic. In the case of a negative logic signal, the signal is active low where the logically true state corresponds to a logic level zero. In the case of a positive logic signal, the signal is active high where the logically true state corresponds to a logic level one. Note that any of the signals described herein may be designed as either negative or positive logic signals. Therefore, in alternate embodiments, those signals described as positive logic signals may be implemented as negative logic signals, and those signals described as negative logic signals may be implemented as positive logic signals.

Furthermore, the terms “assert” or “set” and “negate” (or “deassert” or “clear”) are used herein when referring to the rendering of a signal, status bit, or similar apparatus into its logically true or logically false state, respectively. If the logically true state is a logic level one, the logically false state is a logic level zero. And if the logically true state is a logic level zero, the logically false state is a logic level one.

Those skilled in the art will recognize that the boundaries between logic blocks are merely illustrative and that alternative embodiments may merge logic blocks or circuit elements or impose an alternate decomposition of functionality upon various logic blocks or circuit elements. Thus, it is to be understood that the architectures depicted herein are merely exemplary, and that in fact many other architectures may be implemented which achieve the same functionality.

Any reference to the term “comprising” or “having” or “including” should be applied mutatis mutandis to “consisting” and/or should be applied mutatis mutandis to “consisting essentially of”.

Any arrangement of components to achieve the same functionality is effectively “associated” such that the desired functionality is achieved. Hence, any two components herein combined to achieve a particular functionality may be seen as “associated with” each other such that the desired functionality is achieved, irrespective of architectures or intermedial components. Likewise, any two components so associated can also be viewed as being “operably connected,” or “operably coupled,” to each other to achieve the desired functionality.

Furthermore, those skilled in the art will recognize that boundaries between the above described operations merely illustrative. The multiple operations may be combined into a single operation, a single operation may be distributed in additional operations and operations may be executed at least partially overlapping in time. Moreover, alternative embodiments may include multiple instances of a particular operation, and the order of operations may be altered in various other embodiments.

However, other modifications, variations and alternatives are also possible. The specifications and drawings are, accordingly, to be regarded in an illustrative rather than in a restrictive sense.

In the claims, any reference signs placed between parentheses shall not be construed as limiting the claim. The word ‘comprising’ does not exclude the presence of other elements or steps then those listed in a claim. Furthermore, the terms “a” or “an,” as used herein, are defined as one or more than one. Also, the use of introductory phrases such as “at least one” and “one or more” in the claims should not be construed to imply that the introduction of another claim element by the indefinite articles “a” or “an” limits any particular claim containing such introduced claim element to embodiments containing only one such element, even when the same claim includes the introductory phrases “one or more” or “at least one” and indefinite articles such as “a” or “an.” The same holds true for the use of definite articles. Unless stated otherwise, terms such as “first” and “second” are used to arbitrarily distinguish between the elements such terms describe. Thus, these terms are not necessarily intended to indicate temporal or other prioritization of such elements. The mere fact that certain measures are recited in mutually different claims does not indicate that a combination of these measures cannot be used to advantage.

While certain features of the embodiments have been illustrated and described herein, many modifications, substitutions, changes, and equivalents will now occur to those of ordinary skill in the art. It is, therefore, to be understood that the appended claims are intended to cover all such modifications and changes as fall within the true spirit of the invention.

What is claimed is:

1. A high voltage noise reduction unit, the high voltage noise reduction unit comprising:
an input that is configured to receive a high voltage input signal having a value of at least five hundred volts;
a positive isolated supply unit that is configured to receive the high voltage input signal and to output a positive supply signal that floats on the high voltage input signal;
a negative isolated supply unit that is configured to receive the high voltage input signal and to output a negative supply signal that floats on the high voltage input signal;
a low pass filter that is configured to filter the high voltage input signal to provide a filtered high voltage signal; and
an amplifier that is configured to receive the positive supply signal, to receive the negative supply signal, to receive the filtered high voltage signal, and amplify the filtered high voltage signal to provide a high voltage output signal.

2. The high voltage noise reduction unit according to claim 1, wherein each one of the amplifier, the positive isolated supply unit and the negative isolated supply unit are low voltage components that are subjected to low voltage differences that do not exceed 24 volts.

3. The high voltage noise reduction unit according to claim 1, wherein a voltage level of the filtered high voltage signal equals a voltage level of the high voltage output signal.

4. The high voltage noise reduction unit according to claim 1, wherein the low pass filter comprises a resistor and a capacitor.

5. The high voltage noise reduction unit according to claim 4, wherein an impedance of the resistor is not lower than one megaohms.

6. The high voltage noise reduction unit according to claim 4, wherein the amplifier comprises:
an inverting input;
a noninverting input that is configured to receive filtered high voltage signal;
a negative supply port that is configured to receive the negative supply signal;
a positive supply port that is configured to receive the positive supply signal; and
an output port that is in communication with the inverting input and is configured to output the high voltage output signal.

7. The high voltage noise reduction unit according to claim 6, wherein the low pass filter comprises:
a resistor that is electrically coupled between the input and the noninverting input; and
a capacitor that is in communication with the noninverting input.

8. A method for high voltage noise reduction unit, the method comprising:
receiving a high voltage input signal, by (i) an input of the high voltage noise reduction unit, (ii) a positive isolated supply unit, (iii) a negative isolated supply unit, and (iv) a low pass filter; wherein the high voltage input signal has a value of at least five hundred volts;
outputting, by the positive isolated supply unit, a positive supply signal that floats on the high voltage input signal;
outputting, by the negative isolated supply unit, a negative supply signal that floats on the high voltage input signal;
filtering, by the low pass filter, the high voltage input signal to provide a filtered high voltage signal;
receiving, by an amplifier, the positive supply signal, the negative supply signal and the filtered high voltage signal; and
amplifying the filtered high voltage signal, by the amplifier, to provide a high voltage output signal.

9. The method according to claim 8, wherein each one of the amplifier, the positive isolated supply unit and the negative isolated supply unit are low voltage components that are subjected to low voltage differences that do not exceed 24 volts.

10. The method according to claim 8, wherein a voltage level of the filtered high voltage signal equals a voltage level of the high voltage output signal.

11. The method according to claim 8, wherein the low pass filter comprises a resistor and a capacitor.

12. The method according to claim 11, wherein an impedance of the resistor is not lower than one megaohms.

13. The method according to claim 11, wherein the amplifier comprises an inverting input, a noninverting input, a negative supply port, a positive supply port and an output port that is in communication with the inverting input; wherein the method comprises:
receiving the negative supply signal by the negative supply port;
receiving the positive supply signal by the positive supply port; and
outputting, by the output port, the high voltage output signal.

14. The method according to claim 13, wherein the low pass filter comprises: a resistor that is electrically coupled between the input and the noninverting input; and a capacitor that is in communication with the noninverting input.

15. A high voltage noise reduction unit, the high voltage noise reduction unit comprising:
an input that is configured to receive a high voltage input signal having a value of at least five hundred volts;
a positive isolated supply unit that is configured to receive the high voltage input signal and to output a positive supply signal that floats on the high voltage input signal;
a negative isolated supply unit that is configured to receive the high voltage input signal and to output a negative supply signal that floats on the high voltage input signal;
a low pass filter that is configured to filter the high voltage input signal to provide a filtered high voltage signal; and
a buffer that is configured to receive the positive supply signal, to receive the negative supply signal, to receive the filtered high voltage signal and to output a high voltage output signal that equals the filtered high voltage signal.
